(19) United States
(12) Patent Application Publication
(10) Pub. No.: US 2023/0183851 A1
(43) Pub. Date: Jun. 15, 2023

(54) HIGH-ENTROPY CARBIDE CERAMIC MATERIAL, CARBIDE CERAMIC COATING AND PREPARATION METHODS AND USE THEREOF

(71) Applicant: Lanzhou Institute of Chemical Physics, Chinese Academy of Sciences, Lanzhou City (CN)

(72) Inventors: Hongxuan Li, Lanzhou City (CN); Xiaohong Liu, Lanzhou City (CN); Wenju Xu, Lanzhou City (CN); Bingsen Jia, Lanzhou City (CN); Li Ji, Lanzhou City (CN); Huidi Zhou, Lanzhou City (CN); Jianmin Chen, Lanzhou City (CN)

(21) Appl. No.: 17/833,087

(22) Filed: Jun. 6, 2022

(30) Foreign Application Priority Data
Dec. 14, 2021 (CN) 202111528728.8

(51) Int. Cl. C23C 14/06; C23C 14/00; C23C 14/34

(52) U.S. Cl. CPC C23C 14/0635; C23C 14/0036; C23C 14/3407; C23C 14/3442; C23C 14/3464

(57) ABSTRACT

Disclosed are a high-entropy carbide ceramic material and a preparation method thereof, and also a ceramic coating and its preparation method and use. The high-entropy carbide ceramic material has a chemical composition of (ZrCrTiVNb)C and includes Zr, Cr, Ti, V, and Nb, with a same mole fraction of 6-10%.

### CROSS REFERENCE TO RELATED APPLICATION

This patent application claims the benefit and priority of Chinese Patent Application No. 202111528728.8, entitled “high-entropy carbide ceramic material, a carbide ceramic layer, and preparation methods and use thereof” filed on Dec. 14, 2021, the disclosure of which is incorporated by reference herein in its entirety as part of the present application.

### TECHNICAL FIELD

The present disclosure relates to the technical field of coatings on surfaces of materials, in particular to a high-entropy carbide ceramic material, a carbide ceramic coating, and their preparation methods and use.

### BACKGROUND ART

Carbide ceramic coatings have excellent mechanical properties such as high hardness, high elastic modulus and high wear resistance, and high-temperature stability such as high melting point, high thermal conductivity and ablation resistance. Therefore, the carbide ceramic coatings have been widely used in machinery manufacturing fields such as tools, cutters, and molds, and advanced equipment fields including aviation, aerospace, nuclear energy. However, with the development of the manufacturing industry and advanced equipment, increasing requirements for excellent comprehensive performance of coatings are in need. Conventional unitary carbide coatings (such as WC, ZrC, SiC, and TiC) and binary carbide coatings (such as TiZrC, TiHfC, and TiVC) are gradually unable to meet use requirements under harsh service environments and working conditions. In view of this, researchers have developed ternary, quaternary and multi-element carbide coatings by adding new elements to the basis carbide coatings. However, a problem of low interface compatibility between phases occurs.

“Characteristics of (TiAlCrNbY)C films deposited by reactive magnetron sputtering” (M. Braic, V. Braic, M. Balaceanu, C. N. Zoita, A. Vladescu, E. Grigore. Surface & Coatings Technology, 2010, 204(12): 2010-2014) discloses a high-entropy coating (TiAlCrNbY)C. The coating presents a friction coefficient of 0.05-0.25 while a low hardness of 13-23 GPa, which is lower than that of traditional carbide coatings.

### SUMMARY

In view of this, the present disclosure is to provide a high-entropy carbide ceramic material, a carbide ceramic coating and their preparation methods and use. The high-entropy carbide ceramic material illustrated in the present disclosure presents high hardness, excellent corrosion resistance, and self-lubricating property.

In order to achieve the objects above, the present disclosure provides the following technical solutions.

The present disclosure provides a high-entropy carbide ceramic material of (ZrCrTiVNb)C, which includes Zr, Cr, Ti, V and Nb, with a same mole fraction of 6-10%

In some embodiments, the high-entropy carbide ceramic material presents a face-centered cubic crystal structure.

The present disclosure provides a method for preparing the high-entropy carbide ceramic material described in the technical solutions above, including the following steps:

conducting a multi-arc ion plating deposition on a surface of a substrate to obtain the high-entropy carbide ceramic material of (ZrCrTiVNb)C, wherein a reactive sputtering gas source for the multi-arc ion plating deposition includes a carbon source gas and an inert gas, and cathode targets for the multi-arc ion plating deposition are a Zr metal target, a Cr metal target, a Ti metal target, a V metal target, and a Nb metal target, respectively.

In some embodiments, a flow ratio of the carbon source gas to the inert gas is in the range of (1-2): 1; the reactive sputtering gas source has a pressure of 0.4-0.8 Pa; a current of each cathode target is independently in the range of 50-125 A; a pulsed bias voltage applied is in the range of −400 V to −200 V.

The multi-arc ion plating deposition is conducted at a temperature of 300-400° C.

The present disclosure provides a ceramic coating, which includes a transition layer and a carbide ceramic layer disposed on a surface of the transition layer, wherein the carbide ceramic layer is formed from the high-entropy carbide ceramic material described in the technical solutions above or prepared by the method described in the technical solutions above.

In some embodiments, the carbide ceramic layer has a thickness of 2-10 μm.

In some embodiments, the transition layer is a ZrCrTiVNb metal layer with a thickness of 200-800 nm.

The present disclosure provides a method for preparing the ceramic coating described in the technical solutions above, which includes the following steps:

conducting a multi-arc ion plating deposition on a surface of the transition layer to obtain the high-entropy carbide ceramic of (ZrCrTiVNb)C, wherein a reactive sputtering gas source for the multi-arc ion plating deposition includes a carbon source gas and an inert gas, and the cathode targets for the multi-arc ion plating are a Zr metal target, a Cr metal target, a Ti metal target, a V metal target, a Nb metal target, respectively.

In some embodiments, the transition layer is prepared by a process comprising step of conducting a multi-arc ion plating deposition on a surface of a substrate to obtain the transition layer.

The present disclosure provides use of the ceramic coating described in the technical solutions above or prepared by the method described in the technical solutions above in tools, cutters, molds, aerospace equipment, or nuclear energy equipment.

The present disclosure provides a high-entropy carbide ceramic material of (ZrCrTiVNb)C, which includes Zr, Cr, Ti, V and Nb, with a same mole fraction of 6-10%. The high-entropy ceramic material (ZrCrTiVNb)C disclosed herein is a multi-element metal carbide material including Zr, Cr, Ti, V and Nb, and a combination of Zr, Cr, Ti, V and Nb is controlled, such that a cocktail effect, a high-entropy effect, and a solid solution strengthening effect are achieved, enabling that functions of each of metal elements are exerted to the greatest extent, and thereby synchronously improving mechanical properties, corrosion resistance, high-temperature stability and lubricating wear resistance of the carbide ceramic material. Thus, the high-entropy carbide ceramic material with high hardness, excellent corrosion resistance, and self-lubricating property is obtained.

The present disclosure provides a method for preparing the high-entropy carbide ceramic material described in the technical solutions above, the method including the following steps: conducting a deposition on a surface of a substrate by a multi-arc ion plating to obtain the high-entropy carbide ceramic material of (ZrCrTiVNb)C, wherein a reactive sputtering gas source includes a carbon source gas and an inert gas, and the cathode targets are a Zr metal target, a Cr metal target, a Ti metal target, a V metal target, and a Nb metal target, respectively. By the method illustrated in the present disclosure, the compactness of the high-entropy carbide ceramic material could be improved, which is conducive to improving the mechanical properties of the material.

The present disclosure provides a ceramic coating, which includes a transition layer and a carbide ceramic layer disposed on a surface of the transition layer, wherein the carbide ceramic layer is formed from the high-entropy carbide ceramic material described in the technical solutions above or the high-entropy carbide ceramic material prepared by the method described in the technical solutions above. The ceramic coating according to the present disclosure includes a transition layer, and the transition layer is to eliminate differences in thermal expansion coefficients between the substrate and the carbide ceramic layer, and to improve the bonding force between the carbide ceramic layer and the substrate. The ceramic coating according to the present disclosure includes a carbide ceramic layer of (ZrCrTiVNb)C, which has high hardness, excellent corrosion resistance, and self-lubricating property. As results of examples show, the ceramic coating has a hardness of 26-30 GPa by a nano-indentation method; when being subjected to a dry friction performance test, the ceramic coating presents a friction coefficient of 0.1-0.15 in the stable stage; after 1,000 h in neutral salt spray test, the ceramic coating shows no obvious corrosion spots.

The present disclosure provides a method for preparing the ceramic coating described in the technical solutions above. The method comprises the following steps: the high-entropy carbide ceramic of (ZrCrTiVNb)C is deposited on a surface of the transition layer by multi-arc ion plating deposition. The reactive sputtering gas source for the deposition includes a carbon source gas and an inert gas, the cathode targets for the multi-arc ion plating are a Zr metal target, a Cr metal target, a Ti metal target, a V metal target, a Nb metal target respectively. The carbide ceramic layer deposited on a surface of the transition layer by using this method presents improved compactness, strength, and adhesion strength.

### BRIEF DESCRIPTION OF THE DRAWINGS

FIG. 1 shows an X-ray diffraction spectrum of the ceramic coating prepared in Example 1.

FIG. 2 shows friction coefficient curve of the ceramic coating prepared in Example 1.

FIG. 3 shows the surface of the ceramic coating prepared in Example 1 after 1,000 h in neutral salt spray test.

### DETAILED DESCRIPTION OF THE EMBODIMENTS

The present disclosure provides a high-entropy carbide ceramic material of (ZrCrTiVNb)C, which includes Zr, Cr, Ti, V and Nb, with a same mole fraction of 6-10%.

The high-entropy carbide ceramic material described in the present disclosure has a chemical composition of (ZrCrTiVNb)C.

In the present disclosure, in the (ZrCrTiVNb)C, a mole fraction of Zr is in the range of 6-10%, and preferably 6.5-9%; a mole fraction of Cr is in the range of 6-10%, and preferably 6.5-9%; a mole fraction of Ti is in the range of 6-10%, and preferably 6.5-9%; a mole fraction of V is in the range of 6-10%, preferably 6.5-9%; a mole fraction of Nb is in the range of 6-10%, preferably 6.5-9%; the mole fractions of Zr, Cr, Ti, V and Nb are the same.

In some embodiments of the present disclosure, the high-entropy carbide ceramic material illustrated in this disclosure has a face-centered cubic crystal structure. In some embodiments, the high-entropy carbide ceramic material has a single-phase structure. In some embodiments, the high-entropy carbide ceramic material according to the present disclosure is of a single face-centered cubic (FCC) crystal structure. The FCC crystal structure is a solid-solution single-phase crystal structure, and has high-entropy characteristics. Therefore, the high-entropy carbide ceramic material according to the present disclosure, preferably with the FCC crystal structure, has a typical high-entropy structure, and has high-entropy characteristics.

The present disclosure provides a method for preparing the high-entropy carbide ceramic material described in the technical solutions above, which includes the following steps:

conducting a multi-arc ion plating deposition (hereinafter referred to as first deposition) on a surface of a substrate (hereinafter referred to as first substrate) to obtain the high-entropy carbide ceramic material of (ZrCrTiVNb)C, wherein a reactive sputtering gas source for the multi-arc ion plating deposition includes a carbon source gas and an inert gas (hereinafter referred to as first inert gas), and cathode targets for the multi-arc ion plating deposition are a Zr metal target (hereinafter referred to as first Zr metal target), a Cr metal target (hereinafter referred to as first Cr metal target), a Ti metal target (hereinafter referred to as first Ti metal target), a V metal target (hereinafter referred to as first V metal target) and an Nb metal target (hereinafter referred to as first Nb metal target).

In some embodiments of the present disclosure, the carbon source gas is at least one selected from the group consisting of CH₄ and C₂H₂, and preferably is C₂H₂.

In specific embodiments of the present disclosure, the first inert gas is Ar gas.

In some embodiments of the present disclosure, a flow ratio of the carbon source gas to the first inert gas is in the range of (1-2): 1, and preferably (1.2-1.5): 1.

In some embodiments of the present disclosure, the reactive sputtering gas source has a pressure of 0.4-0.8 Pa, and preferably 0.45-0.7 Pa.

In some embodiments of the present disclosure, the first Zr metal target has a purity of greater than or equal to 99%. In some embodiments, the first Cr metal target has a purity of greater than or equal to 99%. In some embodiments, the first Ti metal target has a purity of greater than or equal to 99%. In some embodiments, the first V metal target has a purity of greater than or equal to 99%. In some embodiments, the first Nb metal target has a purity of greater than or equal to 99%.

In the present disclosure, there is no special requirements for the sources of the first Zr metal target, the first Cr metal target, the first Ti metal target, the first V metal target, and the first Nb metal target. In some embodiments, they are purchased directly.

In some embodiments of the present disclosure, currents of the first Zr metal target, the first Cr metal target, the first Ti metal target, the first V metal target, and the first Nb metal target each are independently in the range of 50-125 A, and preferably 65-120 A.

In some embodiments of the present disclosure, a pulsed bias voltages applied is in the range of −400 V to −200 V, and preferably −250 to −250 V.

In the present disclosure, the first substrate is used as a receiving container when preparing the high-entropy carbide ceramic material by the multi-arc ion plating. In the present disclosure, there are no special requirements for what the first substrate is made of.

In some embodiments of the present disclosure, the first deposition is conducted at a temperature of 300-400° C., and preferably 320-350° C.

The present disclosure provides a ceramic coating, which includes a transition layer and a carbide ceramic layer disposed on a surface of the transition layer, wherein the carbide ceramic layer is formed from the high-entropy carbide ceramic material described in the technical solutions above or the high-entropy carbide ceramic material prepared by the method described in the technical solutions above.

In some embodiments of the present disclosure, the carbide ceramic layer has a thickness of 2-10 μm, and preferably 2.5-8 μm.

In some embodiments of the present disclosure, the transition layer has a chemical composition of ZrCrTiVNb. In some embodiments, the transition layer has a thickness of 200-800 nm, and preferably 250-700 nm.

The present disclosure provides a method for preparing the ceramic coating described in the technical solutions above, which includes the following step:

conducting a multi-arc ion plating deposition on a surface of the transition layer to obtain the high-entropy carbide ceramic layer of (ZrCrTiVNb)C, wherein a reactive sputtering gas source for multi-arc ion plating deposition includes a carbon source gas and an inert gas, and cathode targets for the multi-arc ion plating deposition are a Zr metal target, a Cr metal target, a Ti metal target, a V metal target, and an Nb metal target.

In some embodiments of the present disclosure, the transition layer is prepared by a process, which includes the following step: conducting a multi-arc ion plating deposition (hereinafter referred to as second deposition) on a surface of a substrate (hereinafter referred to as second substrate) to obtain the transition layer.

In the present disclosure, the transition layer has a chemical composition of ZrCrTiVNb. In some embodiments, the multi-arc ion plating deposition is conducted in an inert gas atmosphere (hereinafter referred to as second inert gas). In some embodiments, cathode targets are a Zr metal target (hereinafter referred to as second Zr metal target), a Cr metal target (hereinafter referred to as second Cr metal target), a Ti metal target (hereinafter referred to as second Ti metal target), a V metal target (hereinafter referred to as second V metal target), and an Nb metal target (hereinafter referred to as second Nb metal target).

In the present disclosure, there are no special requirements for the second substrate. In some embodiments of the present disclosure, the second substrate is made of a metal. In specific examples of the present disclosure, the second substrate is made of one selected from the group consisting of a GH4169 high-temperature nickel-based alloy, a 316L stainless steel, and an M2 high-speed steel.

In some embodiments of the present disclosure, before the second deposition of the transition layer, the method according to the present disclosure further includes sequentially subjecting the second substrate to a solvent cleaning and an activation cleaning.

In some embodiments of the present disclosure, the solvent cleaning includes cleaning the second substrate with an organic solvent. In specific examples of the present disclosure, the organic solvent is acetone. In some embodiments of the present disclosure, the cleaning is conducted under an ultrasonic condition. In some embodiments of the present disclosure, the cleaning is conducted for 20 min. In the present disclosure, there are no special requirements for a specific ultrasonic implementation process.

In the present disclosure, the activation cleaning is conducted on the second substrate after the solvent cleaning. In some embodiments of the present disclosure, the activation cleaning is conducted by a multi-arc ion plating system.

In some embodiments of the present disclosure, the activation cleaning is conducted in an inert gas (hereinafter referred to as third inert gas) atmosphere. In some embodiments of the present disclosure, the third inert gas is Ar gas.

In some embodiments of the present disclosure, the third inert gas has a pressure of 1-2 Pa. In some embodiments of the present disclosure, a pulsed bias voltage for the activation cleaning is in the range of of 600-1,000 V, and preferably 650-850 V. In some embodiments of the present disclosure, the activation cleaning is conducted for 30 min.

In some embodiments of the present disclosure, the activation cleaning is conducted in a multi-arc ion plating vacuum chamber. In some embodiments of the present disclosure, before the aeration of inert gas, the vacuum chamber of multi-arc ion plating is pumped to a vacuum degree less than or equal to 6.0×10⁻³ Pa.

In some embodiments of the present disclosure, the activation cleaning of substrate is conducted by plasma generated from glow discharging of inert gas.

In specific examples of the present disclosure, the second inert gas is Ar gas.

In some embodiments of the present disclosure, the second inert gas has a pressure of 0.4-0.8 Pa, and preferably 0.45-0.7 Pa.

In some embodiments of the present disclosure, the second Zr metal target has a purity of greater than or equal to 99%. In some embodiments, the second Cr metal target has a purity of greater than or equal to 99%. In some embodiments, the second Ti metal target has a purity of greater than or equal to 99%. In some embodiments, the second V metal target has a purity of greater than or equal to 99%. In some embodiments, the second Nb metal target has a purity of greater than or equal to 99%.

In the present disclosure, there is no special requirements for the second Zr metal target, the second Cr metal target, the second Ti metal target, the second V metal target, and the second Nb metal target. In some embodiments, they are purchased directly.

In some embodiments of the present disclosure, currents of the second Zr metal target, the second Cr metal target, the second Ti metal target, the second V metal target, and the second Nb metal target each are independently in the range of 50-125 A, and preferably 65-120 A.

In some embodiments of the present disclosure, a pulsed bias voltage applied is in the range of −400 V to −200 V, and preferably −250 V to −250 V.

In some embodiments of the present disclosure, the second deposition is conducted at a temperature of 300-400° C., and preferably 320-350° C.

In the present disclosure, the scope of the method for preparing the carbide ceramic layer is the same as that of the method for preparing the high-entropy carbide ceramic material described above, and will be not repeated herein.

The present disclosure provides use of the ceramic coating or the ceramic coating prepared by the method described in the technical solutions above in tools, cutters, molds, aerospace equipment, or nuclear energy equipment.

The ceramic coating according to the present disclosure has high hardness and excellent corrosion resistance and self-lubricating property.

The technical solutions of the present disclosure are clearly and completely described below in conjunction with examples of the present disclosure. Apparently, the described examples are merely some rather than all of the examples of the present disclosure. All other examples obtained by a person of ordinary skill in the art based on the examples of the present disclosure without creative efforts shall fall within the scope of the present disclosure.

### Example 1

A GH4169 substrate was ultrasonically cleaned with acetone for 20 min and then put into a multi-arc ion plating vacuum chamber. The multi-arc ion plating vacuum chamber was vacuumized to a vacuum degree of 5.0×10⁻³ Pa, and a high-purity Ar gas was introduced therein and a gas pressure was controlled to be 1.5 Pa. A pulsed bias voltage was controlled to be 800 V, and then the GH4169 substrate is cleaned by plasma generated from glow discharging of inert gas for 30 min.

A flow of the Ar gas was controlled to adjust the gas pressure to be 0.6 Pa. The Zr metal target, Cr metal target, Ti metal target, V metal target, and Nb metal target were turn on and currents thereof were adjusted to 115 A, 75 A, 55 A, 75 A, and 125 A, respectively. A pulsed bias voltage was adjusted to −200 V. A transition layer of ZrCrTiVNb was deposited with a thickness of 400 nm.

C₂H₂ was introduced, a flow ratio of the C₂H₂ to the Ar gas was adjusted to be 1.5:1, and a gas pressure was 0.5 Pa. Currents of the Zr target, the Cr target, the Ti target, the V target, and the Nb target were controlled to be 115 A, 75 A, 55 A, 75 A, and 125 A, respectively. A pulsed bias voltage was −200 V. A high-entropy ceramic layer of (ZrCrTiVNb)C was deposited with a thickness of 4.8 μm.

The hardness of ceramic coating prepared in this example was tested by a nano-indentation method. The result shows a hardness of 30 GPa.

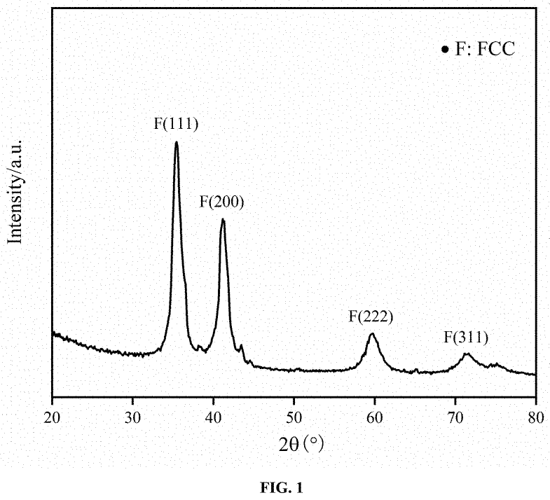

The crystal structure of ceramic coating prepared in this example was analyzed by X-ray diffraction characterization. The result is shown in FIG. 1. From FIG. 1, it can be seen that the ceramic coating prepared in this example presents a simple single-phase crystal structure, i.e. a typical high-entropy structure.

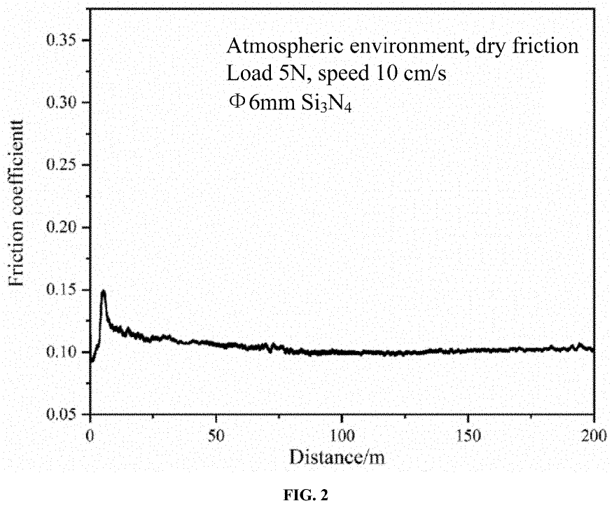

The ceramic coating prepared in this example was subjected to a dry friction performance test. Conditions for the test were as follows: in an atmospheric environment, at a load of 5 N and a speed of 10 cm/s, a counterpart ball of Si₃N₄ with a diameter φ of 6 mm. Test results are shown in FIG. 2. From FIG. 2, it can be seen that the ceramic coating has a friction coefficient of 0.10 in a stable stage.

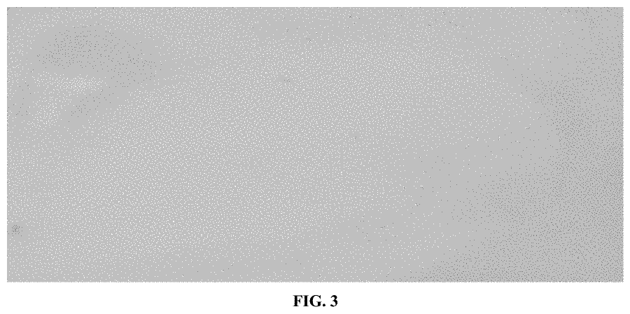

The ceramic coating prepared in this example was subjected to a neutral salt spray test according to the method specified in the national standard 10125-2012, “Corrosion Tests in Artificial Atmospheres—Salt Spray Tests”. The test was specifically as follows. A sodium chloride solution with a pH of 6.5 was prepared and then sprayed into a closed salt spray test box through a spray device. A sample was put in the salt spray test box and intermittently observed whether a surface of the sample was rusted. After 1,000 h. the sample was taken out and observed whether the surface of the sample was rusted. Test results are shown in FIG. 3. From FIG. 3, it can be seen that after the neutral salt spray test for 1,000 h, there are no corrosion spots on the surface of the ceramic coating.

### Example 2

A 316 stainless steel substrate was ultrasonically cleaned with acetone for 20 min and then put into a multi-arc ion plating vacuum chamber. The multi-arc ion plating vacuum chamber was vacuumized to a vacuum degree of 5.0×10⁻³ Pa, and a high-purity Ar gas was introduced therein and a gas pressure was controlled to be 2 Pa. A pulsed bias voltage was controlled to be 600 V, and then the 316 stainless steel substrate is cleaned by plasma generated from glow discharging of inert gas for 30 min.

A flow of the Ar gas was controlled to adjust the gas pressure to be 0.8 Pa. A Zr metal target, a Cr metal target, a Ti metal target, a V metal target, and an Nb metal target were turn on, and currents thereof were adjusted to 120 A, 80 A, 60 A, 80 A, and 120 A, respectively. A pulsed bias voltage was adjusted to −400 V, and a transition layer of ZrCrTiVNb was deposited with a thickness of 200 nm.

C₂H₂ was introduced, a flow ratio of the C₂H₂ to the Ar gas was adjusted to be 1:1, and a gas pressure was 0.5 Pa. Currents of the Zr target, the Cr target, the Ti target, the V target, and the Nb target were controlled to be 120 A, 80 A, 60 A, 80 A, and 120 A, respectively. A pulsed bias voltage was −400 V, and a high-entropy ceramic layer of (ZrCrTiVNb)C was deposited with a thickness of 2.5 μm.

The ceramic coating prepared in this example was tested by same methods as those in Example 1. The test results show that the ceramic coating (ZrCrTiVNb)C prepared in this example has a simple FCC solid solution single-phase crystal structure, and has a hardness of 26 GPa and a friction coefficient of 0.15. After a neutral salt spray test for 1,000 h, there is no obvious corrosion spots on the surface of the ceramic coating.

### Example 3

A GH4169 substrate was ultrasonically cleaned with acetone for 20 min and then put into a multi-arc ion plating vacuum chamber. The multi-arc ion plating vacuum chamber was vacuumized to a vacuum degree of 5.0×10⁻³ Pa, and a high-purity Ar gas was introduced therein and a gas pressure was controlled to be 1 Pa. A pulsed bias voltage was controlled to be 1,000 V, and then the GH4169 substrate is cleaned by plasma generated from glow discharging of inert gas for 30 min.

A flow of the Ar gas was controlled to adjust the gas pressure to be 0.8 Pa. The Zr metal target, a Cr metal target, a Ti metal target, a V metal target and an Nb metal target were turn on, and currents thereof were adjusted to 110 A, 70 A, 55 A, 70 A, and 110 A, respectively. A pulsed bias voltage was adjusted to −200 V, and a transition layer ZrCrTiVNb was deposited with a thickness of 700 nm.

C₂H₂ was introduced, a flow ratio of the C₂H₂ to the Ar gas was adjusted to be 1.5:1, and a gas pressure was 0.5 Pa. Currents of the Zr target, the Cr target, the Ti target, the V target, and the Nb target were controlled to be 110 A, 70 A, 55 A, 70 A, and 110 A, respectively. A pulsed bias voltage was −200 V, and a high-entropy ceramic layer (ZrCrTiVNb)C was deposited with a thickness of 8.5 μm.

The ceramic coating prepared in this example was tested by same methods as Example 1. The test results show that the ceramic coating (ZrCrTiVNb)C prepared in this example has a simple FCC solid solution single-phase crystal structure, and has a hardness of 28 GPa and a friction coefficient of 0.1. After a neutral salt spray test for 1,000 h, there is no obvious corrosion spots on the surface of the ceramic coating.

### Comparative Example 1

A GH4169 substrate was ultrasonically cleaned with acetone for 20 min and then put into a multi-arc ion plating vacuum chamber. The multi-arc ion plating vacuum chamber was vacuumized to a vacuum degree of 5.0×10⁻³ Pa, and a high-purity Ar gas was introduced therein and a gas pressure was controlled to be 1 Pa. A pulsed bias voltage was controlled to be 1,000 V, and then the GH4169 substrate is cleaned by plasma generated from glow discharging of inert gas for 30 min.

A flow of the Ar gas was controlled to adjust the gas pressure to be 0.8 Pa. The Zr metal target, a Cr metal target, a Ti metal target, a V metal target, and an Nb metal target were turned on. Currents of the Zr target, the Cr target, the Ti target, the V target, and the Nb target were controlled to be 110 A, 70 A, 55 A, 70 A, and 110 A, respectively. A pulsed bias voltage was −200 V, and a deposition was conducted, obtaining a transition layer ZrCrTiVNb with a thickness of 700 nm.

C₂H₂ was introduced, a flow ratio of the C₂H₂ to the Ar gas was adjusted to be 0.5:1, and a gas pressure was 0.5 Pa. Currents of the Zr target, the Cr target, the Ti target, the V target, and the Nb target were controlled to be 110 A, 70 A, 55 A, 70 A, and 110 A, respectively. A pulsed bias voltage was −200 V, and a deposition was conducted, obtaining a coating of an amorphous structure with a disordered atomic combination, rather than a high-entropy ceramic layer (ZrCrTiVNb)C.

### Comparative Example 2

A GH4169 substrate was ultrasonically cleaned with acetone for 20 min and then put into a multi-arc ion plating vacuum chamber. The multi-arc ion plating vacuum chamber was vacuumized to a vacuum degree of 5.0×10⁻³ Pa, and a high-purity Ar gas was introduced therein and a gas pressure was controlled to be 1 Pa. A pulsed bias voltage was controlled to be 1,000 V, and the GH4169 substrate is cleaned by plasma generated from glow discharging of inert gas for 30 min.

A flow of the Ar gas was controlled to adjust the gas pressure to be 0.8 Pa. Power supplies of a Zr metal target, a Cr metal target, a Ti metal target, a V metal target, and an Nb metal target were turned on. Currents of the Zr target, the Cr target, the Ti target, the V target, and the Nb target were controlled to be 110 A, 70 A, 55 A, 70 A, and 110 A, respectively. A pulsed bias voltage was −200 V, and a deposition was conducted, obtaining a transition layer ZrCrTiVNb with a thickness of 700 nm.

C₂H₂ was introduced, a flow ratio of the C₂H₂ to the Ar gas was adjusted to be 2.5:1, and a gas pressure was 0.5 Pa. Currents of the Zr target, the Cr target, the Ti target, the V target, and the Nb target were controlled to be 110 A, 70 A, 55 A, 70 A, and 110 A, respectively. A pulsed bias voltage was −200 V, and a coating of an amorphous structure was obtained rather than a high-entropy ceramic layer (ZrCrTiVNb)C of a simple single-phase structure.

The above descriptions are merely preferred embodiments of the present disclosure. It should be noted that a person of ordinary skill in the art may further make several improvements and modifications without departing from the principle of the present disclosure, but such improvements and modifications should be deemed as falling within the scope of the present disclosure.

What is claimed is:

1. A high-entropy carbide ceramic material, wherein the high-entropy carbide ceramic material has a chemical composition of (ZrCrTiVNb)C and comprises Zr, Cr, Ti, V and Nb, with a same mole fraction of 6-10%.

2. The high-entropy carbide ceramic material as claimed in claim 1, wherein the high-entropy carbide ceramic material presents a face-centered cubic crystal structure.

3. A method for preparing the high-entropy carbide ceramic material as claimed in claim 1, comprising step of
conducting a multi-arc ion plating deposition on a surface of a substrate to obtain the high-entropy carbide ceramic material of (ZrCrTiVNb)C,
wherein a reactive sputtering gas source for the multi-arc ion plating deposition comprises a carbon source gas and an inert gas, and cathode targets for the multi-arc ion plating deposition are a Zr metal target, a Cr metal target, a Ti metal target, a V metal target, and an Nb metal target.

4. The method as claimed in claim 3, wherein a flow ratio of the carbon source gas to the inert gas is in the range of (1-2): 1, and the reactive sputtering gas source has a pressure of 0.4-0.8 Pa;
currents of the cathode targets each are independently in the range of 50-125 A, and a pulsed bias voltage applied is in the range of −400 V to −200 V; and
the multi-arc ion plating deposition is conducted at a temperature of 300-400° C.

5. A ceramic coating, comprising a transition layer, and a carbide ceramic layer disposed on the transition layer, wherein
the carbide ceramic layer is formed from the high-entropy carbide ceramic material as claimed in claim 1.

6. The ceramic coating as claimed in claim 5, wherein the carbide ceramic layer has a thickness of 2-10 μm.

7. The ceramic coating as claimed in claim 5, wherein the transition layer has a chemical composition of ZrCrTiVNb and a thickness of 200-800 nm.

8. A method for preparing the ceramic coating as claimed in claim 5, comprising step of
conducting a multi-arc ion plating deposition on a surface of the transition layer to obtain the high-entropy carbide ceramic layer having a chemical composition of (ZrCrTiVNb)C, wherein
a reactive sputtering gas source for the multi-arc ion plating deposition comprises a carbon source gas and an inert gas, and cathode targets for the multi-arc ion plating deposition are a Zr metal target, a Cr metal target, a Ti metal target, a V metal target, and an Nb metal target.

9. The method as claimed in claim 8, wherein the transition layer is prepared by a process comprising step of
conducting a multi-arc ion plating deposition on a surface of a substrate to obtain the transition layer.

10. A method for preparing the high-entropy carbide ceramic material as claimed in claim 2, comprising step of
conducting a multi-arc ion plating deposition on a surface of a substrate to obtain the high-entropy carbide ceramic material of (ZrCrTiVNb)C,
wherein a reactive sputtering gas source for the multi-arc ion plating deposition comprises a carbon source gas and an inert gas, and cathode targets for the multi-arc ion plating deposition are a Zr metal target, a Cr metal target, a Ti metal target, a V metal target, and an Nb metal target.

11. A ceramic coating, comprising a transition layer, and a carbide ceramic layer disposed on the transition layer, wherein
the carbide ceramic layer is formed from the high-entropy carbide ceramic material as claimed in claim 2.

12. A ceramic coating, comprising a transition layer, and a carbide ceramic layer disposed on the transition layer, wherein
the carbide ceramic layer is formed from the high-entropy carbide ceramic material as prepared by the method as claimed in claim 3.

13. A ceramic coating, comprising a transition layer, and a carbide ceramic layer disposed on the transition layer, wherein
the carbide ceramic layer is formed from the high-entropy carbide ceramic material as prepared by the method as claimed in claim 4.
